(19) United States
(12) Patent Application Publication
(10) Pub. No.: US 2022/0302870 A1
(43) Pub. Date: Sep. 22, 2022

(54) Photovoltaic Module Array

(71) Applicant: Prathamesh Acharekar, Thane (IN)

(72) Inventor: Prathamesh Acharekar, Thane (IN)

(21) Appl. No.: 17/206,225

(22) Filed: Mar. 19, 2021

(51) Int. Cl. H02S 20/20; H01L 31/042; H02S 30/10

(52) U.S. Cl. CPC H02S 20/20; H01L 31/042; H02S 30/10

(57) ABSTRACT

A photovoltaic module includes a pyramid-shaped body having an open top end, a closed bottom end, and a hexagonal wall extending between the top end and the bottom end that defines a light receiving cavity. The wall tapers in diameter from the top end to the bottom end and includes slanted light receiving surfaces and planar light receiving surfaces including photovoltaic cells configured to convert sunlight to electricity. The planar light receiving surfaces are disposed between the slanted light receiving surfaces and parallel to the bottom end. The slanted light receiving surfaces slope inward toward the cavity and the bottom end relative to the top end such that the slanted light receiving surfaces face the top end. The planar surfaces form steps in the wall that interconnect the slanted light receiving surfaces. The slanted light receiving surfaces and the planar light receiving surfaces are concentrically aligned relative to one another.

### FIELD OF THE DISCLOSED TECHNOLOGY

The disclosed technology relates to solar panels. More specifically, the present disclosed technology relates to a photovoltaic array including photovoltaic modules or solar cells having multifaceted light receiving surfaces.

### BACKGROUND

Solar panels also known as photovoltaic or PV panels are becoming increasingly popular because they collect clean renewable energy in the form of sunlight and convert that light into electricity which can then be used to provide power to homes and the like. Indeed, solar panels are used for one main purpose and that is to replace other forms of expensive and inefficient methods of generating electricity. Fossil fuel for example is not only expensive, but extremely detrimental to our environment.

A solar panel array is a collection of multiple solar panels that generate electricity as a system. Sunlight hits the panels in an array and produces direct current (DC) electricity. The array is connected to an inverter system, and the inverter converts the DC electricity to usable alternating current (AC) electricity. Conventional solar panel arrays include planar surfaces for maximizing radiation absorbed at any given point. However, solar panels including stepped and inclined surfaces may provide both more power and efficiency due to its multifaceted surfaces. Indeed, they may concentrate power as well as capture more sunlight from the sun over the course of the day without having to move the panels to be perpendicular to the sun's rays.

Accordingly, there is a need for a photovoltaic module and array including multifaceted light receiving surfaces.

### SUMMARY OF THE DISCLOSED TECHNOLOGY

Disclosed herein is a photovoltaic module including an inverted pyramid-shaped body having an open top end, a closed bottom end, the top end opposite the bottom end, a bottom surface at the bottom end, a first side, a second side, the first side opposite the second side, and a hexagonally shaped wall extending between the open top end and the closed bottom end. The hexagonally shaped wall defines a light receiving cavity. The top end includes a perimeter edge and provides access to the light receiving cavity. The hexagonally shaped wall tapers in diameter from the top end to the bottom end and includes a plurality of slanted light receiving surfaces and a plurality of planar light receiving surfaces disposed between the slanted light receiving surfaces. The slanted light receiving surfaces slope downwardly toward the bottom end and inwardly toward the light receiving cavity relative to the top end such that each of the slanted light receiving surfaces faces the top end. The planar surfaces are parallel to the bottom surface, thereby forming steps in the hexagonally shaped wall that interconnect the slanted light receiving surfaces. The slanted light receiving surfaces are concentrically aligned relative to one another. The planar light receiving surfaces are also concentrically aligned relative to one another.

In embodiments, each of the slanted light receiving surfaces includes a plurality of slanted light receiving faces including photovoltaic cells or solar cells configured to convert sunlight to electrical energy and each of the planar light receiving surfaces includes a plurality of planar light receiving faces including photovoltaic cells configured to convert sunlight to electrical energy.

In some embodiments, each of the slanted light receiving surfaces is hexagonally shaped such that each of the slanted light receiving faces of each of the slanted light receiving surfaces defines a side of the hexagon shape and are angled relative to an adjacent slanted light receiving face, and each of the planar light receiving surfaces is hexagonally shaped such that each of the planar light receiving faces of each of the planar light receiving surfaces defines a side of the hexagon shape and are angled relative to an adjacent planar light receiving face.

In certain embodiments, the slanted light receiving surfaces and the planar light receiving surfaces are symmetrical about a longitudinal axis and a lateral axis of the body.

In some embodiments, the bottom surface is hexagonally shaped and includes photovoltaic cells configured to convert sunlight to electrical energy.

In embodiments, the photovoltaic module further includes a rim extending annularly around the perimeter edge of the top end. The rim protrudes outwardly relative to the hexagonally shaped wall and parallel to the planar light receiving surfaces and the bottom surface.

In some embodiments, the slanted light receiving surfaces include a first slanted light receiving surface, a second slanted light receiving surface, and a third slanted light receiving surface, and the planar light receiving surfaces comprise a first planar light receiving surface, a second planar light receiving surface, and a third planar light receiving surface. The first planar light receiving surface extends annularly about the perimeter edge of the top end. The second planar light receiving surface is positioned between the first slanted light receiving surface and the second slanted light receiving surface. The third planar light receiving surface is positioned between the second slanted light receiving surface and the third slanted light receiving surface. The first slanted light receiving surface extends from the perimeter edge of the top end to the second planar light receiving surface. The second slanted light receiving surface extends from the second planar light receiving surface to the third planar light receiving surface. The third slanted light receiving surface extends from the third planar light receiving surface to the bottom surface of the bottom end.

Also disclosed herein is a photovoltaic module array including a plurality of the photovoltaic modules and a housing including a plurality of receptacles each configured to receive one of the photovoltaic modules.

In embodiments, the housing includes a planar upper surface and a planar lower surface, the receptacles extend entirely through the housing between the planar upper surface and the planar lower surface, and the receptacles include a diameter equal to or less than a diameter of the rim such that each of the photovoltaic modules engage the planar upper surface when inserted through the receptacle of the housing, thereby fastening the module to the housing.

In some embodiments, the receptacles include a quantity equal to the quantity of the photovoltaic modules, such that the housing receives all the photovoltaic modules.

“Photovoltaics” refers to “the conversion of light into electricity using semiconducting materials that exhibit the photovoltaic effect”. “Photovoltaic effect” refers to “the generation of voltage and electric current in a material upon exposure to light.” “Photovoltaic module” refers to “an independent assembly of photovoltaic cells or solar cells that converts light into electricity.” A “photovoltaic cell,” also know as a “solar cell,” and used interchangeably therewith throughout the disclosure refers to “an electrical device that converts the energy of light directly into electricity by the photovoltaic effect.” “Inverted” refers to “being upside down or in the opposite position.” “Taper” refers to “diminish or reduce in size, thickness, area toward one end.” “Slant” refers to “diverge or cause to diverge from the vertical or horizontal.” “Slope” refers to “incline from a horizontal or vertical line.” “Concentric” refers to “sharing the same center.” “Cavity” refers to an “empty, or hollowed, space within a solid object.”

Any device or step to a method described in this disclosure can comprise or consist of that which it is a part of, or the parts which make up the device or step. The term “and/or” is inclusive of the items which it joins linguistically and each item by itself. “Substantially” is defined as “at least 95% of the term being described” and any device or aspect of a device or method described herein can be read as “comprising” or “consisting” thereof.

### BRIEF DESCRIPTION OF THE DRAWINGS

FIG. 1A shows a top perspective view of a photovoltaic module of the photovoltaic module array according to one embodiment of the present disclosed technology.

FIG. 1B shows a bottom perspective view of a photovoltaic module of the photovoltaic module array according to one embodiment of the present disclosed technology.

FIG. 2A shows a top plan view of a photovoltaic module of the photovoltaic module array according to one embodiment of the present disclosed technology.

FIG. 2B shows a cross-sectional view of the photovoltaic module of FIG. 2A along line 2-2 according to one embodiment of the present disclosed technology.

FIG. 3 shows an exploded view of a photovoltaic module and the housing, illustrating one manner in which a photovoltaic module is inserted into the receptacles of the housing according to one embodiment of the present disclosed technology.

FIG. 4A shows a top perspective view of the photovoltaic module array according to one embodiment of the present disclosed technology.

FIG. 4B shows a bottom perspective view of the photovoltaic module array according to one embodiment of the present disclosed technology.

FIG. 5A shows a top perspective view of the rim of the photovoltaic module and the photovoltaic module according to one embodiment of the present disclosed technology.

FIG. 5B shows a bottom perspective view of the rim of the photovoltaic module and the photovoltaic module according to one embodiment of the present disclosed technology.

FIG. 5C shows a top plan view of the rim of the photovoltaic module and the photovoltaic module according to one embodiment of the present disclosed technology.

FIG. 5D shows a side elevation view of the photovoltaic module with the rim attached to the perimeter edge of the top end according to one embodiment of the present disclosed technology.

FIG. 6 shows an exploded view of a photovoltaic module and the housing, illustrating one manner in which a photovoltaic module is inserted into the receptacles of the housing according to another embodiment of the present disclosed technology.

FIG. 7A shows a top perspective view the photovoltaic module array according to another embodiment of the present disclosed technology.

FIG. 7B shows a bottom perspective view the photovoltaic module array according to another embodiment of the present disclosed technology.

FIG. 8A shows a top perspective view of the photovoltaic module array according to yet another embodiment of the present disclosed technology.

FIG. 8B shows a front elevation view of the photovoltaic module array according to yet another embodiment of the present disclosed technology.

FIG. 8C shows a side elevation view of the photovoltaic module array according to yet another embodiment of the present disclosed technology.

FIG. 9A shows a top perspective view of the photovoltaic module array according to an alternative embodiment of the present disclosed technology.

FIG. 9B shows a side elevation view of the photovoltaic module array according to an alternative embodiment of the present disclosed technology.

FIG. 9C shows a side elevation view of the photovoltaic module array according to an alternative embodiment of the present disclosed technology.

### DETAILED DESCRIPTION OF EMBODIMENTS OF THE DISCLOSED TECHNOLOGY

The disclosed technology provides photovoltaic module comprising a body having an open top end, a closed bottom end, a bottom surface at the bottom end, and a hexagonally shaped wall defining a light receiving cavity. The hexagonally shaped wall includes slanted light receiving surfaces and planar light receiving surfaces including photovoltaic cells for converting sunlight into electricity. The planar light receiving surfaces are positioned between the slanted light receiving surfaces. The slanted light receiving surfaces slope downwardly toward the bottom end and inwardly toward the cavity such that the slanted light receiving surfaces face the open top end. The planar surfaces form steps in the hexagonally shaped wall that interconnect the slanted light receiving surfaces.

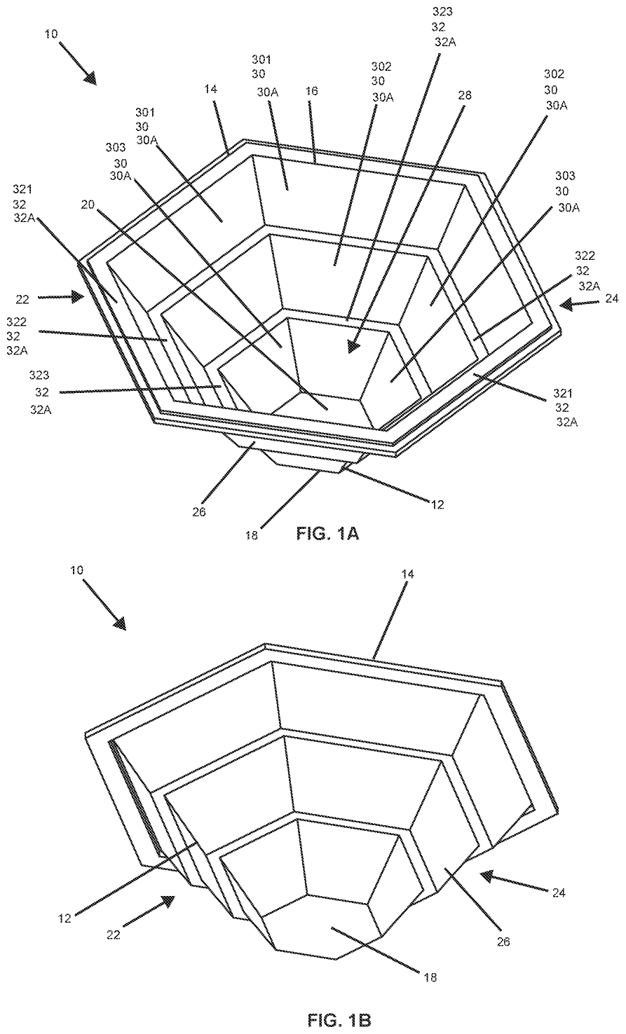

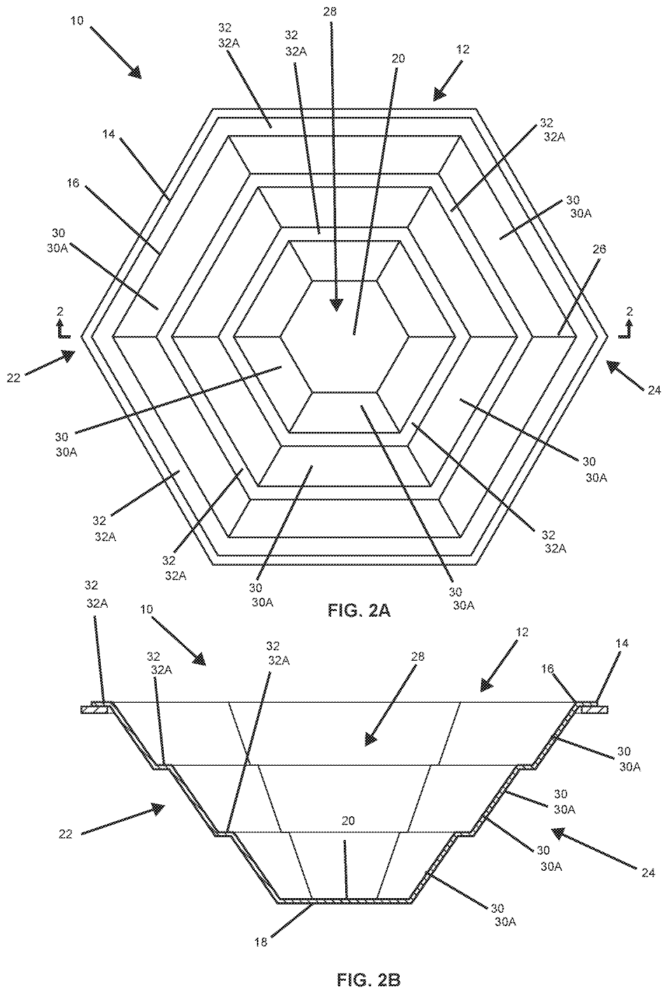

Referring now to FIG. 1A, FIG. 1B, FIG. 2A, FIG. 2B, simultaneously, FIG. 1A shows a top perspective view of a photovoltaic module of the photovoltaic module array according to one embodiment of the present disclosed technology. FIG. 1B shows a bottom perspective view of a photovoltaic module of the photovoltaic module array according to one embodiment of the present disclosed technology. FIG. 2A shows a top plan view of a photovoltaic module of the photovoltaic module array according to one embodiment of the present disclosed technology. FIG. 2B shows a cross-sectional view of the photovoltaic module of FIG. 2A along line 2-2 according to one embodiment of the present disclosed technology.

The present disclosed technology provides a photovoltaic module 10 comprising an inverted pyramid-shaped body 12 having an open top end 14 including a perimeter edge 16, a closed bottom end 18 opposite the open top end 14, a bottom surface 20 at the bottom end 18, a first side 22, a second side 24 opposite the first side 22, and a hexagonally shaped wall 26 extending between the top end 14 and the bottom end 18. The hexagonally shaped wall 26 defines a light receiving cavity 28. The top end 14 provides access to the light receiving cavity 28. The bottom surface 20 is hexagonally shaped and includes photovoltaic cells configured to convert sunlight to electrical energy. These photovoltaic cells may comprise any photovoltaic known in the art that is suitable for converting sunlight to electrical energy/electricity.

The hexagonally shaped wall 26 tapers in diameter from the top end 14 to the bottom end 18 and includes a plurality of slanted light receiving surfaces 30 and a plurality of planar light receiving surfaces 32 disposed between the slanted light receiving surfaces 30. The slanted light receiving surfaces 30 slope downwardly toward the bottom end 18 and inwardly toward the cavity 28 in relation to the top end 14 such that each of the slanted light receiving surfaces 30 faces the top end 14. The planar light receiving surfaces 32 are parallel to the bottom surface 20 forming steps in the hexagonally shaped wall 26 that interconnect the slanted light receiving surfaces 30. The slanted light receiving surfaces 30 are concentrically aligned and/or configured on the hexagonally shaped wall 26 relative to one another. The planar light receiving surfaces 32 are also concentrically aligned and/or configured on the hexagonally shaped wall 26 relative to one another.

Each of the slanted light receiving surfaces 30 comprises a plurality of slanted light receiving faces 30A including photovoltaic cells configured to convert sunlight to electrical energy. Each of the slanted light receiving surfaces 30 is hexagonally shaped such that each of the slanted light receiving faces 30A defines a side of the hexagon shape of the hexagonal slanted light receiving surface and are angled relative to an adjacent slanted light receiving face. The slanted light receiving surfaces 30 are symmetrical about a longitudinal axis and a lateral axis of inverted pyramid-shaped body 12.

Each of the planar light receiving surfaces 32 comprises a plurality of planar light receiving faces 32A including photovoltaic cells configured to convert sunlight to electrical energy. Each of the planar light receiving surfaces 32 is also hexagonally shaped such that each of the planar light receiving faces 32A also define a side of the hexagon shape of the hexagonal planar light receiving surface and are angled relative to an adjacent planar light receiving face. The planar light receiving surfaces 32 are symmetrical about a longitudinal axis and a lateral axis of the inverted pyramid-shaped body 12. These photovoltaic cells may comprise any photovoltaic known in the art that is suitable for converting sunlight to electrical energy/electricity.

Referring to FIG. 1, in embodiments, the slanted light receiving surfaces 30 may comprise a first slanted light receiving surface 301, a second slanted light receiving surface 302, and a third slanted light receiving surface 303 and the planar light receiving surfaces 32 comprise a first planar light receiving surface 321, a second planar light receiving surface 322, and a third planar light receiving surface 323. The first planar light receiving surface 321 extends annularly about the perimeter edge 16 of the top end 14. Note, the first planar light receiving surface 321 may be coterminous with the perimeter edge 16. The second planar light receiving surface 322 is positioned between the first slanted light receiving surface 301 and the second slanted light receiving surface 302. The third planar light receiving surface 323 is positioned between the second slanted light receiving surface 302 and the third slanted light receiving surface 303. The first slanted light receiving surface 301 extends from the perimeter edge and/or the first planar light receiving surface 321 to the second planar light receiving surface 322. The second slanted light receiving surface 302 extends from the second planar light receiving surface 322 to the third planar light receiving surface 323. The third light receiving surface 303 extends from the third planar light receiving surface 323 to the bottom surface 20 of the bottom end 18.

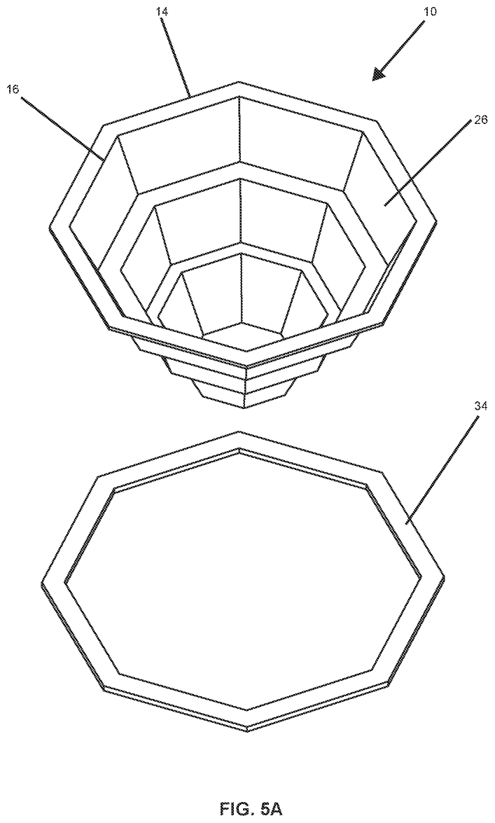

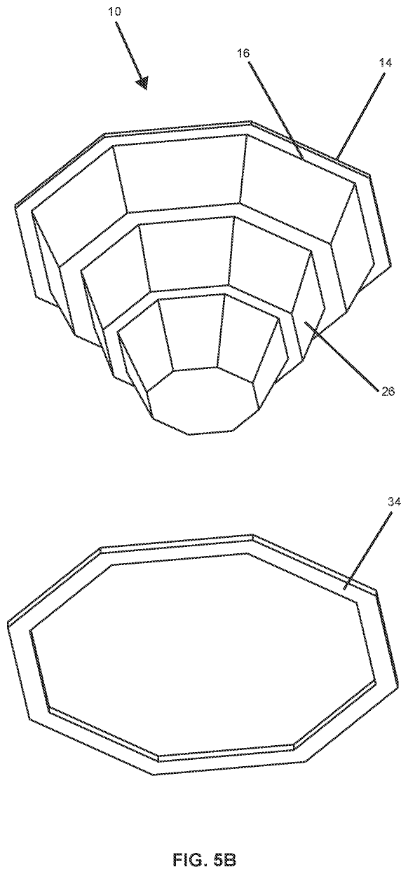

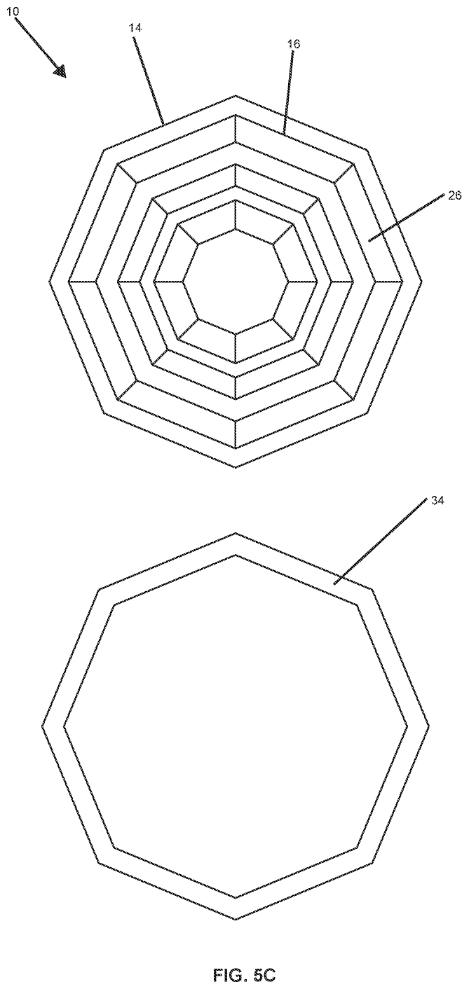

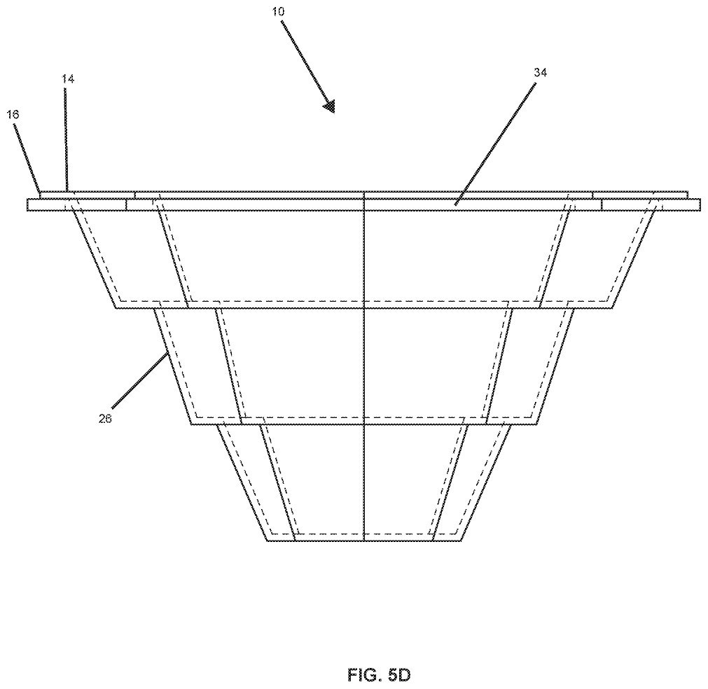

Referring now to FIG. 5A, FIG. 5B, FIG. 5C, and FIG. 5D, simultaneously, FIG. 5A shows a top perspective view of the rim of the photovoltaic module and the photovoltaic module according to one embodiment of the present disclosed technology. FIG. 5B shows a bottom perspective view of the rim of the photovoltaic module and the photovoltaic module according to one embodiment of the present disclosed technology. FIG. 5C shows a top plan view of the rim of the photovoltaic module and the photovoltaic module according to one embodiment of the present disclosed technology. FIG. 5D shows a side elevation view of the photovoltaic module with the rim attached to the perimeter edge of the top end according to one embodiment of the present disclosed technology.

In embodiments, the photovoltaic module 10 further comprises a rim 34 extending annularly around the perimeter edge 16 of the top end 14. The rim 34 protrudes outwardly relative to the hexagonally shaped wall 26 and parallel to the planar light receiving surfaces 32 and the bottom surface 20. In some embodiments, the rim 34 is a separate and discrete structure from the photovoltaic module 10 and is selectively mounted onto module 10. In these embodiments, the rim 34 includes an opening 36 for receiving the module 10 therethrough. The rim 34 includes a diameter less than a diameter of the perimeter edge 16 such that the rim 34 may engage the perimeter edge 16 and fasten thereto. The rim 34 includes a hexagonal shape to fit over the hexagonally shaped wall 26 in lock and key fashion.

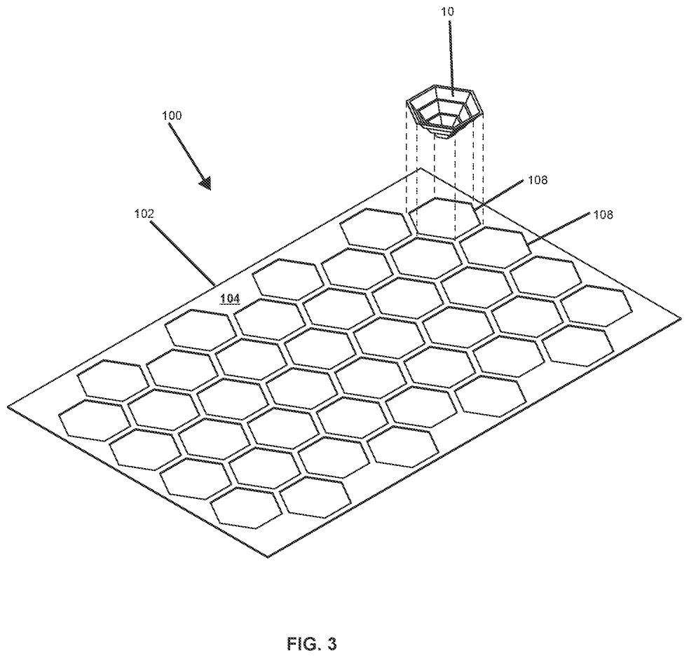

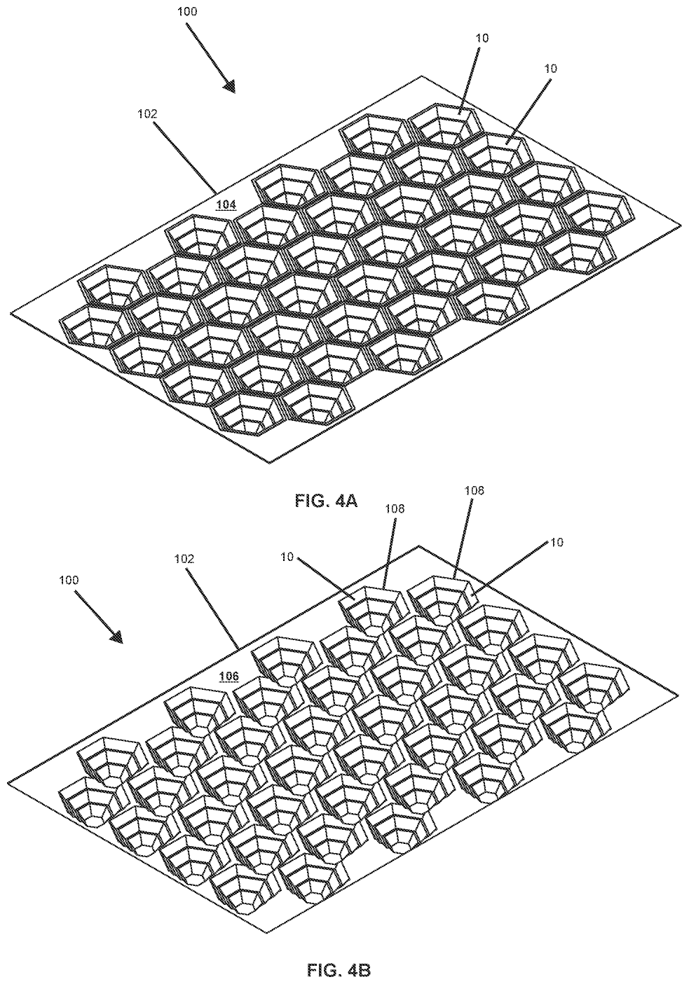

Referring now to FIG. 3, FIG. 4A, and FIG. 4B, simultaneously, FIG. 3 shows an exploded view of a photovoltaic module and the housing, illustrating one manner in which a photovoltaic module is inserted into the receptacles of the housing according to one embodiment of the present disclosed technology. FIG. 4A shows a top perspective view of the photovoltaic module array according to one embodiment of the present disclosed technology. FIG. 4B shows a bottom perspective view of the photovoltaic module array according to one embodiment of the present disclosed technology. The present disclosed technology provided a photovoltaic array 100 including a plurality of the photovoltaic modules 10. The photovoltaic array comprises a housing 102 including a planar upper surface 104, a planar lower surface 106, and a plurality of receptacles 108 extending entirely through the housing 102 between the planar upper surface 104 and the planar lower surface 106. The receptacles 108 are interspaced evenly throughout the housing 102. Each of the receptacles 108 is configured to receive one of the photovoltaic modules 10 therethrough for mounting the modules 10 onto the housing 102. The diameter of each of the receptacles 108 is equal to or smaller than the diameter of the rim 34 and/or the perimeter edge 16 of the module 10 such that the modules 10 may engage the planar upper surfaces 104 of the housing 102. In some embodiments, the receptacles 108 include a quantity equal to the quantity of the photovoltaic modules 10, such that the housing 102 may receive all the photovoltaic modules 10. When, the modules 10 have been inserted into all the receptacles 108, the resultant photovoltaic array 102 forms a photovoltaic module pattern in which the modules 10 are arranged into uneven columns and/or rows of modules 10.

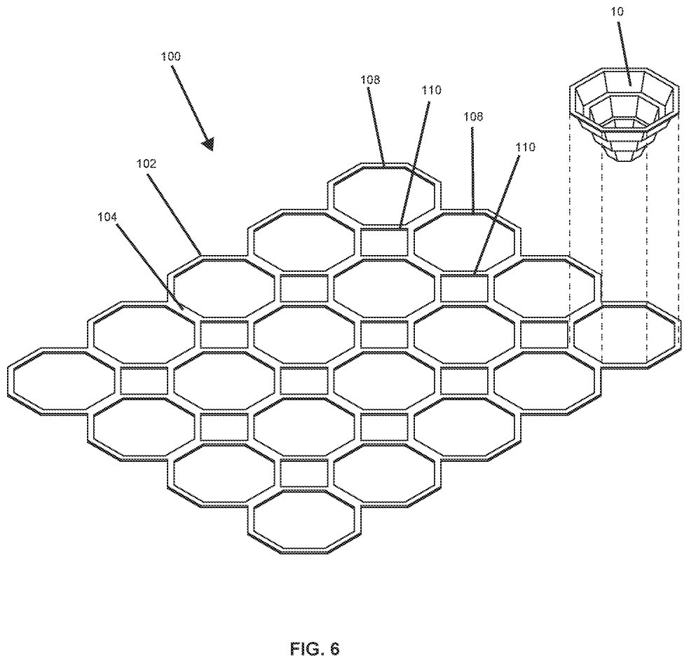

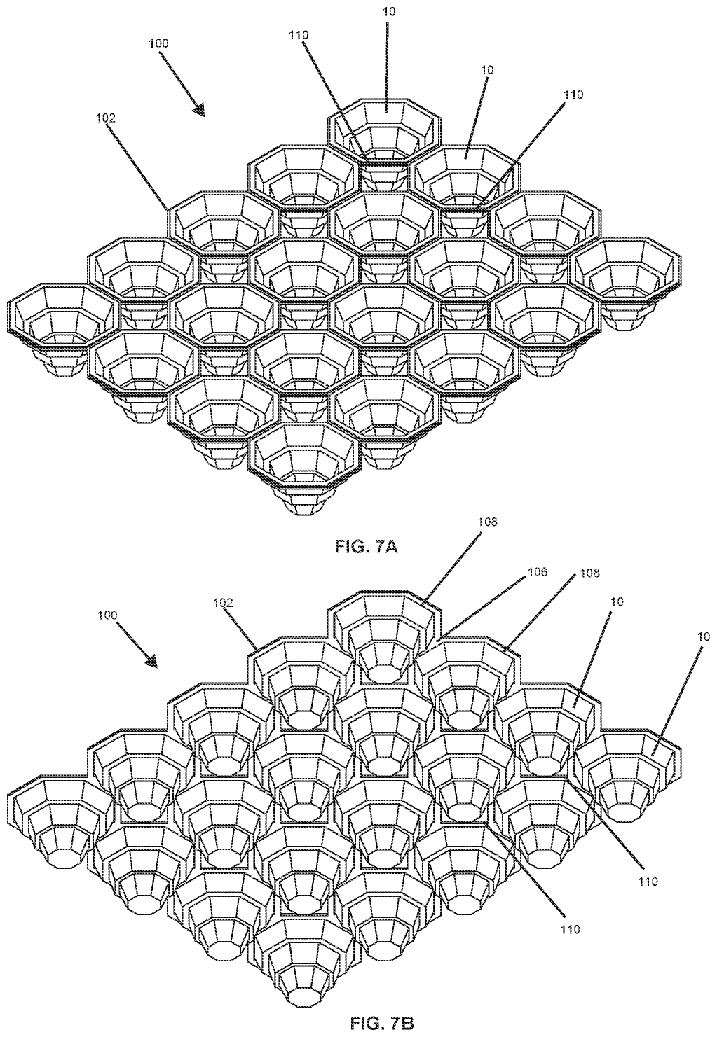

Referring now to FIG. 6, FIG. 7A, and FIG. 7B, simultaneously, FIG. 6 shows an exploded view of a photovoltaic module and the housing, illustrating one manner in which a photovoltaic module is inserted into the receptacles of the housing according to another embodiment of the present disclosed technology. FIG. 7A shows a top perspective view the photovoltaic module array according to another embodiment of the present disclosed technology. FIG. 7B shows a bottom perspective view the photovoltaic module array according to another embodiment of the present disclosed technology. In embodiments, the plurality of receptacles 108 of the housing 102 are spaced apart by quadrilateral openings 110 extending through the planar upper surface 104 and the planar lower surface 106. When, the modules 10 have been inserted into all the receptacles 108, the resultant photovoltaic array 102 forms a photovoltaic module pattern in which the modules 10 are arranged into even columns and/or rows of modules 10.

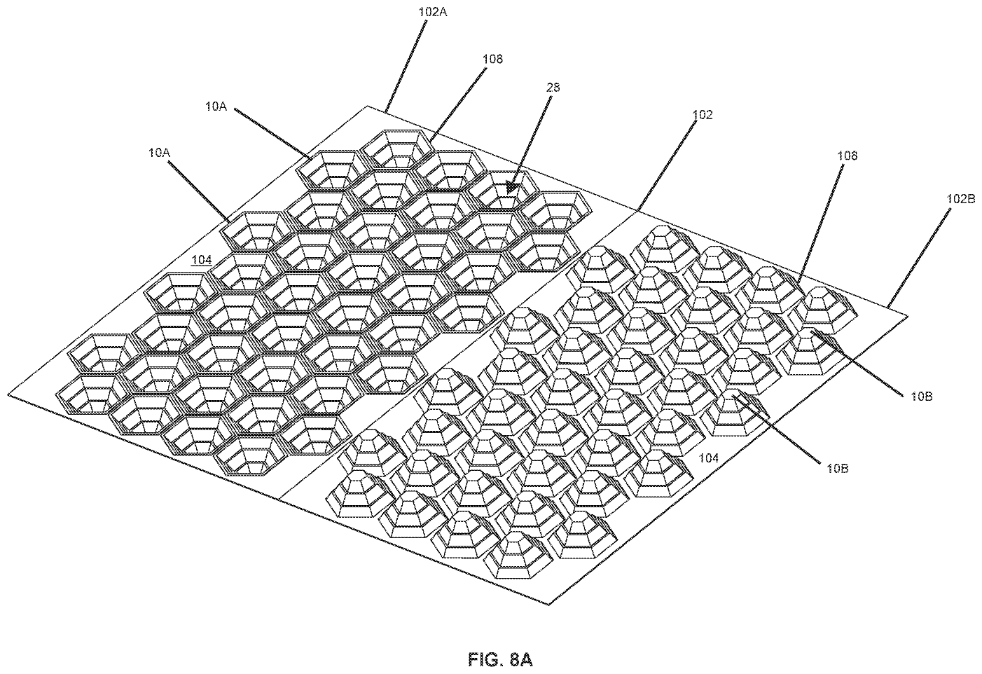

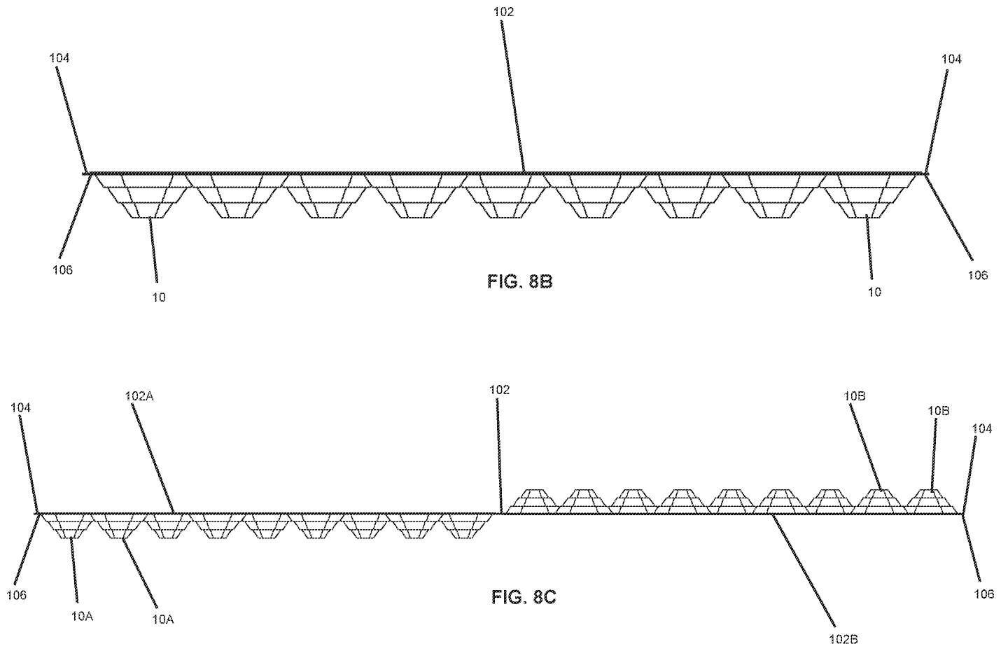

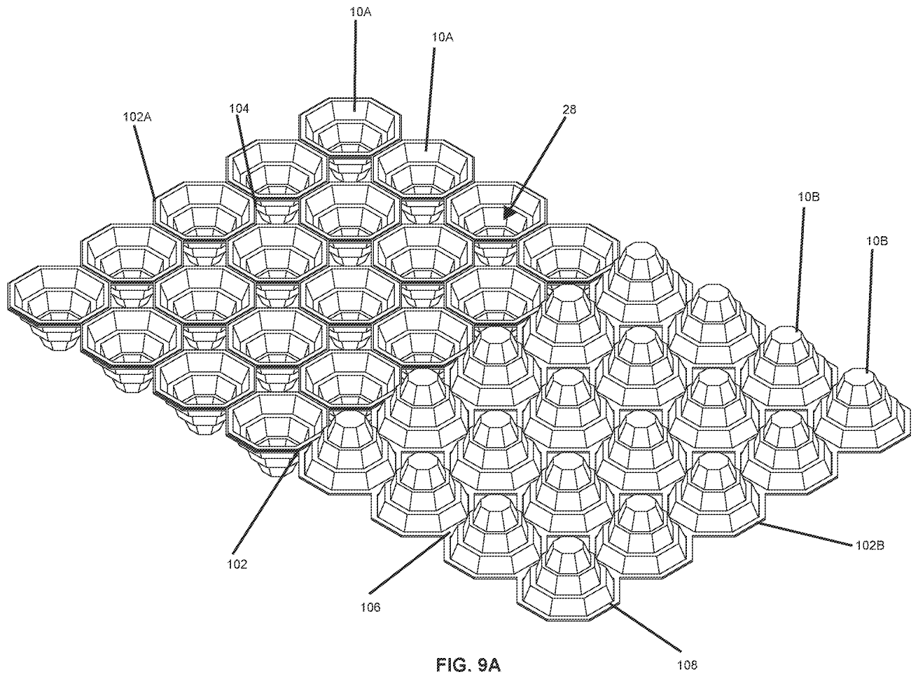

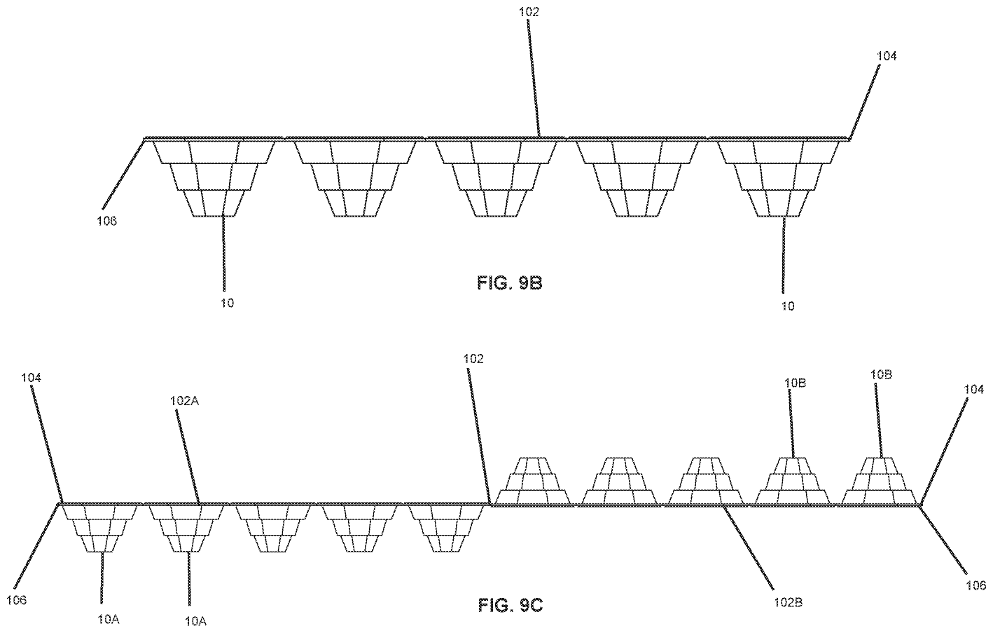

Referring now to FIG. 8A, FIG. 8B, FIG. 8C, FIG. 9A, FIG. 9B, and FIG. 9C simultaneously, FIG. 8A shows a top perspective view of the photovoltaic module array according to yet another embodiment of the present disclosed technology. FIG. 8B shows a front elevation view of the photovoltaic module array according to yet another embodiment of the present disclosed technology. FIG. 8C shows a side elevation view of the photovoltaic module array according to yet another embodiment of the present disclosed technology. FIG. 9A shows a top perspective view of the photovoltaic module array according to an alternative embodiment of the present disclosed technology. FIG. 9B shows a side elevation view of the photovoltaic module array according to an alternative embodiment of the present disclosed technology. FIG. 9C shows a side elevation view of the photovoltaic module array according to an alternative embodiment of the present disclosed technology. In embodiments, the housing 102 includes a first half 102A and a second half 102B opposite the first half 102A, in which the photovoltaic modules 10 on the first half 102A are positioned in opposing directions with respect to the photovoltaic modules positioned on the second half 102B. The first half 102A comprises a first plurality of photovoltaic modules 10A positioned within the receptacles 108 such that the light receiving cavity 28 extends downwardly through the upper planar surface 104 and lower planar surface 106 with respect to the upper planar surface 104 such that the light receiving cavity 28 is accessible via the upper planer surface 104 and protrudes outwardly with respect to the lower planar surface 106. In this way, the light receiving cavities 28 of the first plurality of modules 10A is flush with the upper planar surface 10. The second half 102B comprises a second plurality of photovoltaic modules 10B positioned within the receptacles 108 such that the light receiving cavity 28 extends upwardly through the lower planar surface 106 such that the light receiving cavity 28 is accessible via the lower planar surface 106 and protrudes outwardly with respect to the upper planar surface. In this way, the light receiving cavities 28 of the second plurality of modules 10B are flush with the lower planar surface 106.

Any device or step to a method described in this disclosure can comprise or consist of that which it is a part of, or the parts which make up the device or step. The term “and/or” is inclusive of the items which it joins linguistically and each item by itself.

For purposes of this disclosure, the term “substantially” is defined as “at least 95% of” the term which it modifies.

Any device or aspect of the technology can “comprise” or “consist of” the item it modifies, whether explicitly written as such or otherwise.

When the term “or” is used, it creates a group which has within either term being connected by the conjunction as well as both terms being connected by the conjunction.

While the disclosed technology has been disclosed with specific reference to the above embodiments, a person having ordinary skill in the art will recognize that changes can be made in form and detail without departing from the spirit and the scope of the disclosed technology. The described embodiments are to be considered in all respects only as illustrative and not restrictive. All changes that come within the meaning and range of equivalency of the claims are to be embraced within their scope. Combinations of any of the methods and apparatuses described hereinabove are also contemplated and within the scope of the invention.

What is claimed is:

1. A photovoltaic module, comprising:
an inverted pyramid-shaped body having an open top end, a closed bottom end, the top end opposite the bottom end, a bottom surface at the bottom end, a first side, a second side, the first side opposite the second side, and a hexagonally shaped wall extending between the open top end and the closed bottom end, the hexagonally shaped wall defining a light receiving cavity, the top end including a perimeter edge and providing access to the light receiving cavity, the hexagonally shaped wall tapering in diameter from the top end to the bottom end and including a plurality of slanted light receiving surfaces and a plurality of planar light receiving surfaces disposed between the slanted light receiving surfaces, the slanted light receiving surfaces sloping downwardly toward the bottom end and inwardly toward the light receiving cavity relative to the top end such that each of the slanted light receiving surfaces faces the top end, the planar surfaces parallel to the bottom surface forming steps in the hexagonally shaped wall that interconnect the slanted light receiving surfaces, the slanted light receiving surfaces concentrically aligned relative to one another, the planar light receiving surfaces concentrically aligned relative to one another.

2. The photovoltaic module of claim 1, wherein each of the slanted light receiving surfaces comprises a plurality of slanted light receiving faces including photovoltaic cells configured to convert sunlight to electrical energy.

3. The photovoltaic module of claim 2, wherein each of the planar light receiving surfaces comprises a plurality of planar light receiving faces including photovoltaic cells configured to convert sunlight to electrical energy.

4. The photovoltaic module of claim 3, wherein each of the slanted light receiving surfaces is hexagonally shaped such that each of the slanted light receiving faces of each of the slanted light receiving surfaces defines a side of the hexagon shape and are angled relative to an adjacent slanted light receiving face.

5. The photovoltaic module of claim 4, wherein each of the planar light receiving surfaces is hexagonally shaped such that each of the planar light receiving faces of each of the planar light receiving surfaces defines a side of the hexagon shape and are angled relative to an adjacent planar light receiving face.

6. The photovoltaic module of claim 5, wherein the slanted light receiving surfaces are symmetrical about a longitudinal axis and a lateral axis of the body.

7. The photovoltaic module of claim 6, wherein the planar light receiving surfaces are symmetrical about a longitudinal axis and a lateral axis of the body.

8. The photovoltaic module of claim 7, wherein the bottom surface is hexagonally shaped and includes photovoltaic cells configured to convert sunlight to electrical energy.

9. The photovoltaic module of claim 8, further comprising a rim extending annularly around the perimeter edge of the top end, the rim protruding outwardly relative to the hexagonally shaped wall and parallel to the planar light receiving surfaces and the bottom surface.

10. The photovoltaic module of claim 9, wherein:
the slanted light receiving surfaces comprise a first slanted light receiving surface, a second slanted light receiving surface, and a third slanted light receiving surface;
the planar light receiving surfaces comprise a first planar light receiving surface, a second planar light receiving surface, and a third planar light receiving surface;
the first planar light receiving surface extends annularly about the perimeter edge of the top end, the second planar light receiving surface is positioned between the first slanted light receiving surface and the second slanted light receiving surface, and the third planar light receiving surface is positioned between the second slanted light receiving surface and the third slanted light receiving surface;
the first slanted light receiving surface extends from the perimeter edge of the top end to the second planar light receiving surface, the second slanted light receiving surface extends from the second planar light receiving surface to the third planar light receiving surface, and the third slanted light receiving surface extends from the third planar light receiving surface to the bottom surface of the bottom end.

11. A photovoltaic module array, comprising:
a plurality of photovoltaic modules, each of the photovoltaic modules including an inverted pyramid-shaped body having an open top end, a closed bottom end, the top end opposite the bottom end, a bottom surface at the bottom end, a first side, a second side, the first side opposite the second side, a hexagonally shaped wall extending between the open top end and the closed bottom end, the hexagonally shaped wall defining a light receiving cavity, the top end including a perimeter edge and providing access to the light receiving cavity, the hexagonally shaped wall tapering in diameter from the top end to the bottom end and including a plurality of slanted light receiving surfaces and a plurality of planar light receiving surfaces disposed between the slanted light receiving surfaces, the slanted light receiving surfaces sloping downwardly toward the bottom end and inwardly toward the cavity relative to the top end such that each of the slanted light receiving surfaces faces the open top end, the planar surfaces parallel to the bottom surface forming steps in the hexagonally shaped wall that interconnect the slanted light receiving surfaces, the slanted light receiving surfaces concentrically aligned relative to one another, the planar light receiving surfaces concentrically aligned relative to one another; and
a housing including a plurality of receptacles each configured to receive one of the photovoltaic modules.

12. The photovoltaic module of claim 11, wherein each of the plurality of photovoltaic modules comprises a rim extending annularly around the perimeter edge of the top end, the rim protruding outwardly relative to the hexagonally shaped wall and parallel to the planar light receiving surfaces and the bottom surface.

13. The photovoltaic module array of claim 12, wherein:
the housing includes a planar upper surface and a planar lower surface;
the receptacles extend entirely through the housing between the planar upper surface and the planar lower surface; and
the receptacles include a diameter equal to or less than a diameter of the rim such that each of the photovoltaic modules engage the planar upper surface when inserted through the receptacle of the housing, thereby fastening the module to the housing.

14. The photovoltaic module array of claim 13, wherein the plurality of receptacles are spaced apart by quadrilateral openings extending through the planar upper surface and the planar lower surface of the housing.

15. The photovoltaic module array of claim 14, wherein:
the housing comprises a first half and a second half; and
the photovoltaic modules include a first plurality of photovoltaic modules disposed on the first half and a second plurality of photovoltaic modules disposed on the second half, the first plurality of photovoltaic modules positioned in opposing directions with respect to the second plurality of photovoltaic modules.

16. The photovoltaic module array of claim 15, wherein the receptacles include a quantity equal to the quantity of the photovoltaic modules, such that the housing receives all the photovoltaic modules.

17. The photovoltaic module of claim 16, wherein:
each of the slanted light receiving surfaces comprises a plurality of slanted light receiving faces including photovoltaic cells configured to convert sunlight to electrical energy; and
each of the planar light receiving surfaces comprises a plurality of planar light receiving faces including photovoltaic cells configured to convert sunlight to electrical energy.

18. The photovoltaic module of claim 17, wherein:
each of the slanted light receiving surfaces is hexagonally shaped such that each of the slanted light receiving faces of each of the slanted light receiving surfaces defines a side of the hexagon shape and are angled relative to an adjacent slanted light receiving; and
each of the planar light receiving surfaces is hexagonally shaped such that each of the planar light receiving faces of each of the planar light receiving surfaces defines a side of the hexagon shape and are angled relative to an adjacent planar light receiving face.

19. The photovoltaic module of claim 18, wherein:
the slanted light receiving surfaces are symmetrical about a longitudinal axis and a lateral axis of the body; and
the planar light receiving surfaces are symmetrical about a longitudinal axis and a lateral axis of the body.

20. The photovoltaic module of claim 19, wherein the bottom surface is hexagonally shaped and includes photovoltaic cells configured to convert sunlight to electrical energy.
